(19) United States
(12) Patent Application Publication
(10) Pub. No.: US 2008/0070356 A1
(43) Pub. Date: Mar. 20, 2008

(54) Trench replacement gate process for transistors having elevated source and drain regions

(75) Inventors: Laura A. Brown, Pleasant Valley, NY (US); Philip A. Fisher, Fishkill, NY (US); Huicai Zhong, Wappingers Falls, NY (US); Johannes Groschopf, Wainsdorf (DE)

Correspondence Address: MCDERMOTT WILL & EMERY LLP, 600 13TH STREET, N.W., WASHINGTON, DC, 20005-3096, US

(73) Assignee: ADVANCED MICRO DEVICES, INC.

(21) Appl. No.: 11/520,607

(22) Filed: Sep. 14, 2006

(51) Int. Cl. H01L 21/336; H01L 21/8234

(52) U.S. Cl. 438/197; 438/300; 438/303

(57) ABSTRACT

The method for forming a semiconductor device arrangement with raised source/drains includes depositing a raised source/drain layer on a substrate, followed by a sacrificial layer on the raised source/drain layer. A trench is formed in the sacrificial layer and the raised source/drain layer, and sidewall spacers are formed within the trench. A replacement gate is formed between the sidewall spacers and the sacrificial layer is removed to expose the raised source/drain regions. The sidewall spacers may then be removed from the sidewalls of the replacement gate, leaving the replacement gate a defined distance from the raised source/drain regions.

### FIELD OF THE INVENTION

The present invention relates to the field of semiconductor manufacture, and more particularly, to the formation of semiconductor devices having elevated source and drain regions.

### BACKGROUND OF THE INVENTION

The present invention relates to integrated circuits (ICs) and methods of manufacturing integrated circuits. More particularly, the present application relates to a method of manufacturing integrated circuits having transistors with elevated source and drain regions and high-k gate dielectrics.

Currently, deep-submicron complementary metal oxide semiconductor (CMOS) is the primary technology for ultra-large scale integrated (ULSI) devices. Over the last two decades, reducing the size of CMOS transistors and increasing transistor density on ICs has been a principal focus of the microelectronics industry. An ultra-large scale integrated circuit can include over 1 million transistors.

The ULSI circuit can include CMOS field effect transistors (FETS) which have semiconductor gates disposed between drain and source regions. The drain and source regions are typically heavily doped with a P-type dopant (boron) or an N-type dopant (phosphorous).

The drain and source regions generally include a thin extension (shallow source and drain extension) that is disposed partially underneath the gate to enhance the transistor performance.

Shallow source and drain extensions help to achieve immunity to short-channel effects which degrade transistor performance for both N-channel and P-channel transistors. Short-channel effects can cause threshold voltage roll-off and drain-induced barrier-lowering. Shallow source and drain extensions and, hence, controlling short-channel effects, are particularly important as transistors become smaller.

Conventional techniques utilize a double implant process to form shallow source and drain extensions. According to the conventional process, the source and drain extensions are formed by providing a transistor gate structure without sidewall spacers on a top surface of a silicon substrate. The silicon substrate is doped on both sides of the gate structure via a conventional doping process, such as, a diffusion process or an ion implantation process. Without the sidewall spacers, the doping process introduces dopants into a thin region just below the top surface of the substrate to form the drain and source extensions as well as to partially form the drain and source regions.

After the drain and source extensions are formed, silicon dioxide spacers, which abut lateral sides of the gate structure, are provided over the source and drain extensions. With the silicon dioxide spacers in place, the substrate is doped a second time to form deep source and drain regions. During formation of the deep source and drain regions, further doping of the source and drain extensions is inhibited due to the blocking capability of the silicon dioxide spacers.

As the size of transistors disposed on ICs decreases, transistors with shallow and ultra-shallow source/drain extensions become more difficult to manufacture. For example, a small transistor may require ultra-shallow source and drain extensions with a junction depth of less than 30 nanometer (nm). Forming source and drain extensions with junction depths of less than 30 nm is very difficult using conventional fabrication techniques. Conventional ion implantation techniques have difficulty maintaining shallow source and drain extensions because point defects generated in the bulk semiconductor substrate during ion implantation can cause the dopant to more easily diffuse (transient enhanced diffusion, TED). The diffusion often extends the source and drain extension vertically downward into the bulk semiconductor substrate. Also, conventional ion implantation and diffusion-doping techniques make transistors on the IC susceptible to short-channel effects, which result in a dopant profile tail distribution that extends deep into the substrate.

The source and drain regions can be raised by selective silicon (Si) epitaxy to make connections to source and drain contacts less difficult. The raised source and drain regions provide additional material for contact silicidation processes and reduce deep source/drain junction resistance and source/drain series resistance. However, the epitaxy process that forms the raised source and drain regions generally requires high temperatures exceeding 1000° C. (e.g., 1100-1200° C.). These high temperatures increase the thermal budget of the process and can adversely affect the formation of steep retrograde well regions and ultra shallow source/drain extensions.

The high temperatures, often referred to as a high thermal budget, can produce significant thermal diffusion which can cause shorts between the source and drain region (between the source/drain extensions). The potential for shorting between the source and drain region increases as gate lengths decrease.

In addition, high temperature processes over 750 to 800° C. can cause dielectric materials with a high dielectric constant (k) to react with the substrate (e.g., silicon). High-k (k>8) gate dielectrics are desirable as critical transistor dimensions continue to decrease. The reduction of critical dimensions requires that the thickness of the gate oxide also be reduced. A major drawback to the decreased gate oxide thickness (e.g., <30 ANG.) is that direct tunneling gate leakage current increases as gate oxide thickness decreases. To suppress gate leakage current, material with a high dielectric constant (k) can be used as a gate dielectric instead of the conventional gate oxides, such as thermally grown silicon dioxide.

High-k gate dielectric materials have advantages over conventional gate oxides. A high-k gate dielectric material with the same effective electrical thickness (same capacitive effect) as a thermal oxide is much thicker physically than the conventional oxide. Being thicker physically, the high-k dielectric gate insulator is less susceptible to direct tunnel leakage current. Tunnel leakage current is exponentially proportional to the gate dielectric thickness. Thus, using a high-k dielectric gate insulator significantly reduces the direct tunneling current flow through the gate insulator.

High-k materials include, for example, aluminum oxide (Al₂O₃), titanium dioxide (TiO₂), and tantalum pentaoxide (TaO₅). Aluminum oxide has a dielectric constant (k) equal to eight (8) and is relatively easy to make as a gate insulator for a very small transistor. Small transistors often have a physical gate length of less than 80 nm.

### SUMMARY OF THE INVENTION

There is a need for a method of making semiconductor devices that have elevated source and drain regions, is able to employ high-k dielectrics, and allows the raised source and drain regions to be composed of materials that can be deposited in a blanket manner.

This and other needs are met by embodiments of the present invention which provide a method of forming a semiconductor arrangement comprising the steps of depositing a raised source/drain layer on a substrate and depositing a sacrificial layer on the raised source/drain layer. A trench is formed in the sacrificial layer and the raised source/drain layer. A gate is then formed within the trench and the sacrificial layer is removed.

The embodiments of the method of the present invention allows for the provision of a raised source/drain layer that is composed of materials that are blanket deposited. Formation of a sacrificial layer and a trench within that sacrificial layer and the raised source/drain layer permits the formation of a replacement gate. Removal of the sacrificial layer, as provided in certain embodiments of the invention, along with a spacer, produces a replacement gate that is separated from the raised source/drain by a defined distance.

The earlier stated needs are met by other embodiments of the present invention which provide a method of forming a semiconductor device with raised and source drain regions, comprising the steps of depositing a bi-layer on a substrate, the bi-layer having a source and drain layer, and a sacrificial layer on the source and drain layer. The sacrificial layer is removed. The trench is then formed having sidewalls on the source and drain layer. A gate is formed on the substrate that is spaced from the sidewalls of the trench in the source and drain layer.

The foregoing and other features, aspects and advantages of the present invention will be more apparent from the following detailed description of the present invention when taken in conjunction with the accompanying drawings.

### BRIEF DESCRIPTION OF THE DRAWINGS

FIG. 1 is a schematic depiction of a cross-sectional view of a portion of a semiconductor wafer during one phase of manufacture in accordance with embodiments of the method of the present invention.

FIG. 2 shows the structure of FIG. 1 following the deposition of a spacer layer within the trench formed during the manufacturing step shown in FIG. 1.

FIG. 3 depicts the structure of FIG. 2 after an etching process to form sidewalls spacers in the trench in accordance with embodiments of the present invention.

FIG. 4 shows the structure of FIG. 3 following the formation of a replacement gate within the trench, in accordance with embodiments of the present invention.

FIG. 5 depicts the structure of FIG. 4 after the removal of the sacrificial layer in accordance with embodiments of the present invention.

FIG. 6 shows the structure FIG. 5 following the removal of the sidewall spacers in accordance with embodiments of the present invention.

### DETAILED DESCRIPTION OF THE INVENTION

The present invention addresses and solves problems related to the formation of semiconductor devices having raised source/drains, and in particular, the formation process of raised source/drains and the incorporation of this process with replacement gate technology. This is achieved, at least in part, by the present invention in the provision of a blanket deposition of a raised source/drain layer on the substrate, followed by deposition of a sacrificial layer on the raised source/drain layer. The trench is formed in the sacrificial layer and the raised source/drain, and a gate is formed within the trench. The sacrificial layer is then removed, leaving the raised source/drain area and the replacement gate. A blanket deposition of the raised source/drain layer thereby avoids the disadvantages attendant to formation of raised source/drains by selective silicon epitaxy and allows a larger number of materials to be employed as the raised source/drain material.

FIG. 1 is a schematic depiction of a portion of a semiconductor wafer during one phase of manufacture in accordance with embodiments of the present invention. A substrate 10, such as a silicon substrate, is provided. The raised source/drain layer 12 is blanket deposited on the top surface of the substrate 10. The raised source/drain layer 12 may be made of silicon or polysilicon, for example. However, other materials suitable for blanket deposition and for use as a raised source/drain layer may be employed without departing from the scope of the present invention. The thickness of the raised source/drain layer 12 is advantageously made to a final thickness for the raised source/drains that are desired. As an example, the thickness of the raised source/drain layer 12 is between 300-700 [symbol] and in certain preferred embodiments, is approximately 500

[symbol]

The sacrificial layer 14 is then deposited on top of the raised source/drain layer 12. The sacrificial layer 14 should comprise material that is preferentially etched to leave the raised source/drain layer 12 intact. An example of a suitable material is silicon dioxide (SiO₂). The deposition of the raised source/drain layer 12 and the sacrificial layer 14 may be by any conventional methodology, such as chemical vapor deposition of (CVD). The thickness of the sacrificial layer 14 should be such that the combination of the thickness of the source/drain layer 12 and the sacrificial layer 14 is equal to the desired thickness of the finished gate.

Following the deposition of the raised source/drain layer 12 and the sacrificial layer 14 on the substrate 10, patterning and etching is performed to create a trench 16 in the sacrificial layer 14 and the raised source/drain layer 12, stopping at the substrate 10. A dry etch may be performed, such as a plasma etch. It is advantageous to perform the plasma etch with an etch chemistry that will etch the sacrificial layer 14 and the raised source/drain layer 12 preferentially without significantly etching the substrate 10. An example of such an etch chemistry is silicon tetrachloride/chlorine, for example. However, this is exemplary only, as other etch chemistries may be employed depending upon the materials used in the sacrificial layer 14 on the raised source/drain layer 12.

The width of the trench 16 is such as to accommodate the desired final width of the replacement gate and the desired spacing between the sides of the replacement gate and the raised source/drains. For example, the width of the trench 16 may be between about 80 and about 100 [symbol] for example, although other widths may be provided without departing from the present invention.

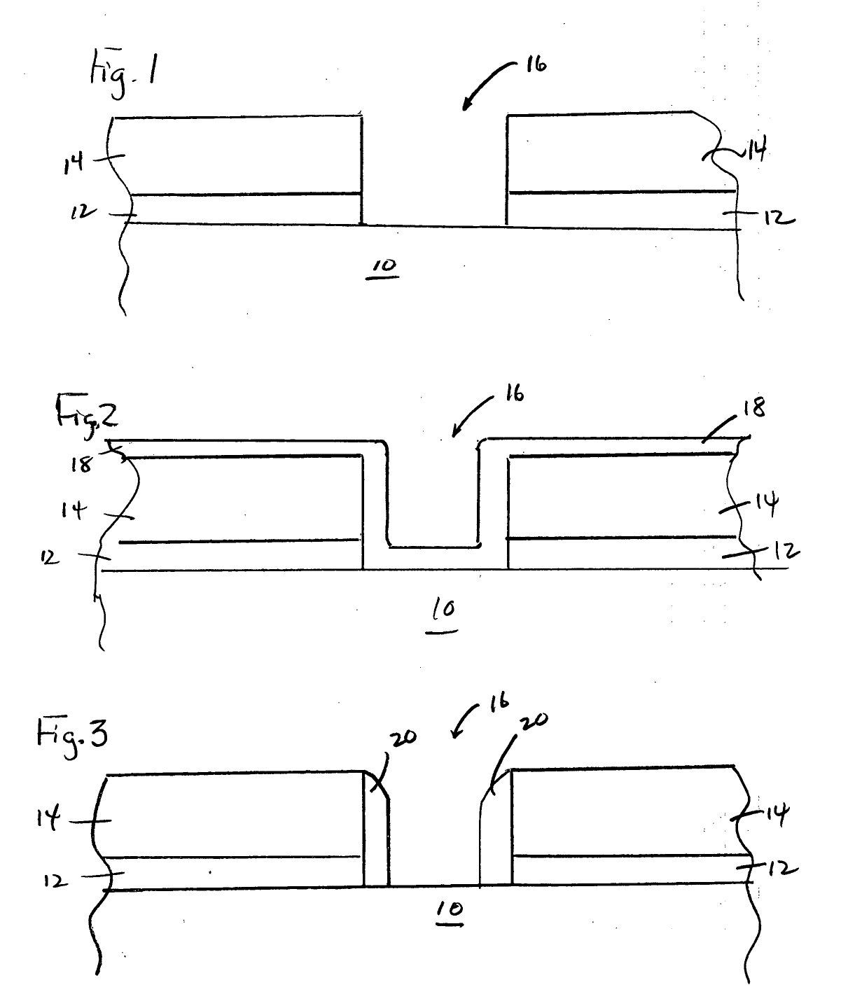

FIG. 2 shows the structure of FIG. 1 following the deposition of a spacer layer 18 within the trench 16 and on top of the sacrificial layer 14. The spacer layer 18 may be made of any suitable material, but should be one that is preferentially etchable with respect to the eventual replacement gate material, the raised source/drain material, and the substrate material. In exemplary embodiments, the material formed in the space layer 18 is silicon nitride. An exemplary thickness for the spacer layer 18 is between about 20 and about 40 [symbol] for example.

After the spacer 18 has been deposited, an etching is performed to create sidewall spacers 20 from the spacer layer 18. This is achieved, for example, by an anisotropic etching such as a reactive ion etch. This removes the horizontal surfaces of the silicon layer 18, leaving the vertical sidewall spacers 20. The substrate 10 is exposed within the trench 16.

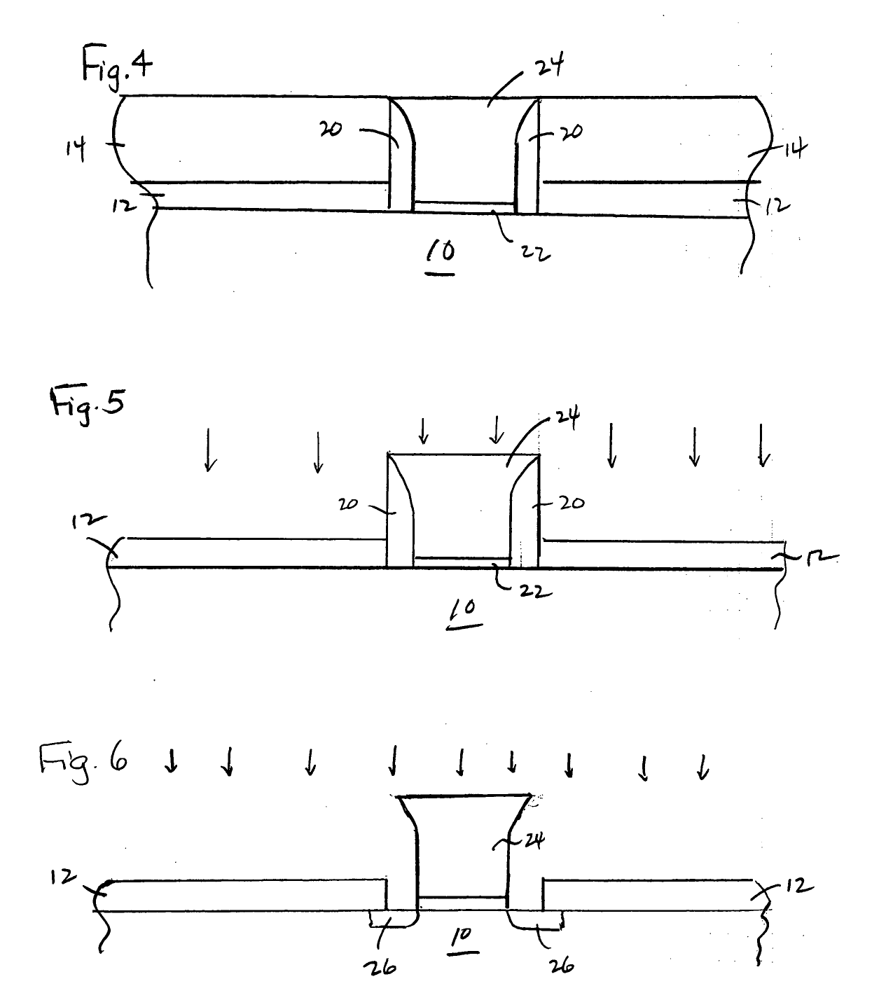

FIG. 4 shows the structure of FIG. 3 following the deposition of a gate dielectric layer 22 and the formation of the replacement gate 24. This involves the deposition of the replacement gate material, which may be polysilicon, or other suitable conductive or semi conductive material. This is followed a polishing to remove the excess gate material from the top of the sacrificial layer 16. Gate dielectric layer 22 may be a high k gate dielectric material or a more conventional gate dielectric material.

Following the formation of the replacement gate 24, the sacrificial layer 16 is removed, as depicted in FIG. 5. When the sacrificial layer 16 is made of silicon dioxide, for example, the removal process may be preformed by a buffered oxide etch, for example. This leaves the structure of FIG. 5 in which the raised source/drain is provided on either side of sidewall spacers 20 and the replacement gate 24. Heavy doping can then be performed to dope both the raised source/drain regions 12, and the replacement gate 24. The spacers 20 and the replacement gate 24 prevent doping of the substrate 10 underneath these elements.

FIG. 6 depicts the structure of FIG. 5 following the removal of the sidewall spacers 20. When the sidewall spacers 20 are made of silicon nitride, for example, a hot phosphoric etch may be used to remove the sidewall spacers 20. Once the sidewall spacers 20 are removed, a light doping may be performed to create source/drain extension areas 26 in the substrate 10. A conventional implantation process may be used to create the source/drain extensions 26.

As can be seen in FIG. 6, the raised source/drain regions 12 are a defined distance from the replacement gate 24, and may be 30 [symbol] for example. The removal of the sidewall spacers 20 from the final structure allows for their replacement by a lower k dielectric material, among other advantages.

The present invention thus provides an improved process for creating semiconductor devices with raised source/drain regions and a replacement gate that is a defined distance from the raised source/drain regions. This process allows a wider range of materials to be employed as the raised source/drain regions, and overcomes certain disadvantages of epitaxial growth processes.

Although the present invention has been described and illustrated in detail, it is to be clearly understood that the same is by way of illustration and example only and is not to be taken by way of limitation, the scope of the present invention being limited only by the terms of the appended claims.

What is claimed is:

1. A method of forming a semiconductor device arrangement, comprising:
depositing a raised source/drain layer on a substrate;
depositing a sacrificial layer on the raised source/drain layer;
forming a trench in the sacrificial layer and the raised source/drain layer;
forming a gate within the trench; and
removing the sacrificial layer.

2. The method of claim 1, further comprising forming a spacer layer in the trench prior to forming a gate.

3. The method of claim 2, further comprising etching the spacer layer to form sidewall spacers on sidewalls of the trench prior to forming a gate.

4. The method of claim 3, further comprising removing the sidewall spacers after removing the sacrificial layer.

5. The method of claim 4, wherein the raised source/drain layer comprises silicon.

6. The method of claim 4, wherein the raised source/drain layer comprises polysilicon.

7. The method of claim 4, wherein the raised source/drain layer comprises SiGe.

8. The method of claim 4, wherein the step of forming a spacer layer includes controlling a thickness of the spacer layer to control width of the gate.

9. A method of forming a semiconductor device with raised source and drain regions, comprising the steps:
depositing a bi-layer on a substrate, the bi-layer having a source and drain layer, and a sacrificial layer on the source and drain layer;
removing the sacrificial layer;
forming a trench having sidewalls in the source and drain layer; and
forming a gate on the substrate and spaced from the sidewall of the trench in the source and drain layer.

10. The method of claim 9, further comprising forming a trench in the sacrificial layer, and forming sidewall spacers within the trench in the sacrificial layer and within the trench in the source and drain layer prior to forming the gate.

11. The method of claim 10, wherein the step of forming sidewall spacers includes depositing a spacer layer within the trench in the source and drain layer and the trench in the sacrificial layer.

12. The method of claim 11, wherein the step of forming sidewall spacers includes etching the spacer layer.

13. The method of claim 12, wherein the source and drain layer comprises silicon.

14. The method of claim 12, wherein the source and drain layer comprises polysilicon.

15. The method of claim 12, wherein the source and drain layer comprises SiGe.

16. The method of claim 12, further comprising controlling the thickness of the spacer layer during depositing of the spacer layer to thereby control spacing of the gate from the sidewalls of the trench in the source and drain layer.

17. The method of claim 16, further comprising removing the sidewall spacers after forming the gate.

18. The method of claim 17, wherein the step of forming a gate includes depositing gate material on the spacer layer prior to etching of the spacer layer.
